(19) United States
(12) Patent Application Publication
(10) Pub. No.: US 2026/0170977 A1
(43) Pub. Date: Jun. 18, 2026

(54) Display Device

(71) Applicant: LG Display Co., Ltd., Seoul (KR)

(72) Inventors: Joonyoung Kwon, Paju-si (KR); Kyeongseob Kwon, Paju-si (KR)

(21) Appl. No.: 19/181,775

(22) Filed: Apr. 17, 2025

(30) Foreign Application Priority Data
Dec. 17, 2024 (KR) 10-2024-0188832

(51) Int. Cl. G09G 3/00; G09G 3/3233; H10K 59/131

(52) U.S. Cl. CPC G09G 3/006; G09G 3/3233; H10K 59/131; G09G 2300/0842; G09G 2330/10; G09G 2330/12

(57) ABSTRACT

A display device includes a display panel including a display area, a bonding area, and a link area, a link line tester disposed in the bonding area of the display panel and configured to detect link line defects in the link area, a flexible circuit board having one side connected to the bonding area of the display panel and including a data driving circuit connected to the link line tester through second data link lines, and a repair line surrounding an outermost link line among the second data link lines and a side of the link line tester and disposed between the link area tester and the display area.

### CROSS-REFERENCE TO RELATED APPLICATION

This application claims the benefit of priority of the Republic of Korea Patent Application No. 10-2024-0188832 filed on December 17, 2024, which is hereby incorporated by reference in its entirety.

### BACKGROUND

### Field of Technology

The present disclosure relates to a display device, and more particularly, to a display device having a Chip On Film (COF) structure, which includes a link line tester for detecting a defect in a link line and a repair line for repairing a disconnection in a data link line.

### Discussion of the Related Art

An organic light emitting display device includes two electrodes and an organic light emitting layer disposed between them. Electrons injected from one electrode, which is a cathode, and holes injected from the other electrode, which is an anode, recombine in the organic emission layer to form excitons, which emit light as they release energy.

An organic light emitting display device includes a plurality of pixels including an organic light emitting element comprising a cathode, an anode, and an organic light emitting layer, and each pixel is formed with a plurality of transistors and one or more capacitors for driving the organic light emitting element.

Pixel defects may occur due to deviations in the characteristics of the elements provided in each pixel of such organic light emitting display devices, open circuits or short circuits in the wiring, etc.

### SUMMARY

Accordingly, the present disclosure is directed to providing a display device that substantially obviates one or more problems due to limitations and disadvantages of the related art.

The present disclosure provides a display device including a link line tester that facilitates detection of a link line defect and a repair line that may repair a data link line when a disconnection occurs.

Additional advantages and features of the disclosure will be set forth in part in the description which follows and in part will become apparent to those having ordinary skill in the art upon examination of the following or may be learned from practice of the disclosure. The technical benefits and other advantages of the disclosure may be realized and attained by the structure particularly pointed out in the written description and claims hereof as well as the appended drawings. To achieve these and other benefits and in accordance with the purpose of the disclosure, as embodied and broadly described herein, there is provided a display device including a display panel including a display area, a bonding area, and a link area, a link line tester disposed in the bonding area of the display panel, and a repair line capable of repairing a disconnection in a data link line that connects the link line tester and a data drive circuit of a flexible circuit board.

The display area of the display panel may include a plurality of pixels, the bonding area may include a plurality of pads, and the link area may include a plurality of link lines.

The repair line may be connected to the data driving circuit and may surround the outermost link line among the second data link lines connecting the data driving circuit and the link line tester, and may be disposed in the link area between the link line tester and the display area.

A link line tester may be disposed in a bonding area of a display panel and may output a test signal provided through at least one pad among a plurality of pads to a plurality of link lines to detect a defect in the link line.

It is to be understood that both the foregoing general description and the following detailed description of the present disclosure are exemplary and explanatory and are intended to provide further explanation of the disclosure.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a schematic drawing showing an organic light emitting display device.

FIG. 2 is a drawing showing an organic light emitting display device according to an embodiment of the present disclosure.

FIG. 3 is a diagram showing a circuit diagram for one pixel of FIG. 2 according to an embodiment of the present disclosure.

FIG. 4 is a drawing showing a link line tester and a repair line according to one embodiment of the present disclosure.

FIG. 5 is a drawing showing a link line tester and a repair line according to another embodiment of the present disclosure.

FIG. 6 is a drawing showing an example to which the repair line of embodiments of the present disclosure is applied.

FIG. 7 is a drawing showing a pixel tester according to one embodiment of the present disclosure.

### DETAILED DESCRIPTION

Hereinafter, a display device according to the present disclosure will be described in detail with reference to the attached drawings.

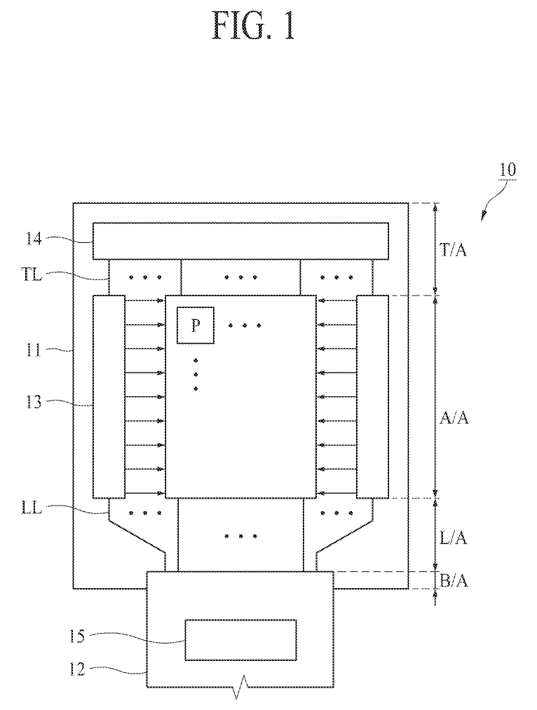

FIG. 1 is a schematic drawing showing an organic light emitting display device.

As illustrated in FIG. 1, the organic light emitting display device 10 may be configured to include a display panel 11, a gate driving circuit 13, a data driving circuit 15, and a flexible circuit board 12.

The display panel 11 may include a test area T/A, a display area A/A, a link area L/A, and a bonding area B/A. The remaining area of the display panel 11 except for the display area A/A may be a non-display area and may be covered by a bezel or the like.

A plurality of pixels P connected to a plurality of gate lines and a plurality of data lines may be formed in the display area A/A of the display panel 11, and each pixel P may include an organic light emitting element (not shown).

The gate driving circuit 13 may be configured in the form of a gate in panel (GIP) on both sides of the display area A/A. The gate driving circuit 13 may output a gate signal to a plurality of gate lines of the display area A/A.

The data driving circuit 15 may be configured in the form of a chip and may be configured in the form of a chip-on-film on a flexible circuit board 12. The data driving circuit 15 may output a data voltage to a plurality of data lines of the display area A/A through a plurality of transmission lines of the flexible circuit board 12 and a plurality of link lines LL of the link area L/A.

A flexible circuit board 12 may be attached to a bonding area B/A of a display panel 11, and a plurality of transmission lines may be formed to connect to an external circuit. The flexible circuit board 12 may transmit control signals provided from an external circuit to a data driving circuit 15 through a plurality of transmission lines. In addition, the flexible circuit board 12 may transmits control signals to a gate driving circuit 13 through a plurality of link lines LL of a link area L/A.

A test circuit 14 for testing the operating status of the display area A/A may be configured in the test area T/A of the display panel 11. The test circuit 14 may provide test signals applied from an external device (not shown) to the gate driving circuit 13 and a plurality of pixels P of the display area A/A through a plurality of test lines TL. The test circuit 14 may test the performance of each pixel P of the display area A/A that is illuminated by the test signal. The test signal may include a control signal for operating the gate driving circuit 13 and a data voltage provided to each pixel P.

In this organic light emitting display device 10, a narrow bezel may be implemented by reducing the width of the lower non-display area by bending the link area L/A of the display panel 11. To this end, the thickness of a protective layer such as an inorganic film may be reduced in the link area L/A of the display panel 11, thereby maintaining the radius of curvature according to the bending of the link area L/A. At this time, a plurality of link lines LL formed in the link area L/A may be opened or shorted due to an external impact due to the reduced thickness of the protective layer. Accordingly, it is necessary to test for defects due to opening and shorting of a plurality of link lines LL.

However, since the test circuit 14 of the above-described organic light emitting display device 10 may be disposed in the test area T/A, that is, the area between the display area A/A of the display panel 11 and the upper portion of the display panel 11, it is impossible to test for defects in a plurality of link lines LL of the link area L/A.

That is, the test circuit 14 of the organic light emitting display device 10 may output a test signal applied from an external device to the gate driving circuit 13 and a plurality of pixels P of the display area A/A. Therefore, the test signal output from the test circuit 14 cannot be transmitted to a plurality of link lines LL of the link area L/A, and thus the organic light emitting display device 10 cannot detect open or short defects of a plurality of link lines LL.

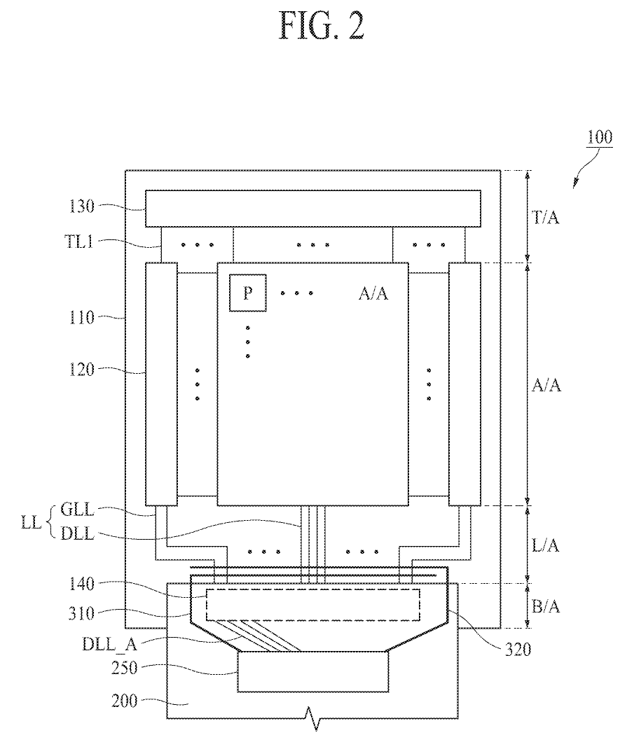

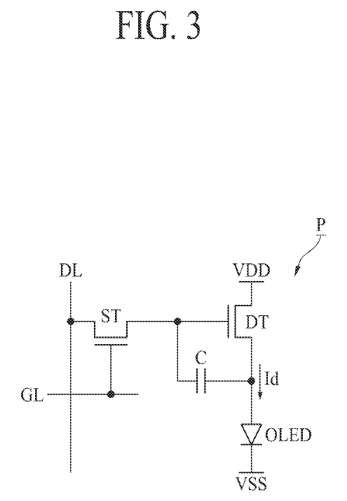

FIG. 2 is a drawing showing an organic light emitting display device according to one embodiment of the present disclosure, and FIG. 3 is a drawing showing a circuit diagram for one pixel of FIG. 2 according to an embodiment of the present disclosure.

Referring to FIGS. 2 and 3, the organic light emitting display device 100 of the present embodiment may include a display panel 110, driving circuits for driving the display panel 110, and a tester for testing the display panel 110.

The display panel 110 may include a test area T/A, a display area A/A, a link area L/A, and a bonding area B/A.

A pixel tester 130 (e.g., a circuit) may be disposed in the test area T/A of the display panel 110. The pixel tester 130 may be configured with a pixel performance test circuit capable of testing the operating status of each pixel P of the display panel 110. The pixel tester 130 may apply a test signal provided from a test device to the gate driving circuit 120 and each pixel P of the display panel 110 through a plurality of first test lines TL1. The pixel tester 130 may test the operating performance of each pixel P of the display panel 110, for example, the emission brightness of the pixel P, according to the test signal. The configuration of the pixel tester 130 will be described in detail later with reference to the drawings.

A plurality of pixels P may be disposed in a matrix form in the display area A/A of the display panel 110. Each of the plurality of pixels P may be disposed at each intersection area of a plurality of gate lines GL and a plurality of data lines DL. In addition, a power line for supplying a driving voltage VDD and a base voltage VSS to each of the plurality of pixels P may be further formed in the display area A/A.

Each of the plurality of pixels P may include a switching TFT ST, a driving TFT DT, a storage capacitor C, and an organic light emitting diode OLED.

The switching TFT ST may be connected to the gate line GL and performs a switching operation according to a gate signal applied through the gate line GL. A gate electrode of the switching TFT ST may be connected to the gate line GL, a drain electrode may be connected to a data line DL, and a source electrode may be connected to a gate electrode of a driving TFT DT. The switching TFT ST may be turned on according to a gate signal applied through the gate line GL and may provide a data voltage applied through the data line DL to the driving TFT DT.

The driving TFT DT may be switched to the data voltage supplied from the switching TFT ST. The driving TFT DT may control the magnitude of a current, i.e., a driving current (Id), flowing from the driving voltage VDD to the organic light emitting diode OLED according to a gate source voltage (Vgs). The gate electrode of the driving TFT DT may be connected to the switching TFT ST, the drain electrode may be supplied with the driving voltage VDD through a power line, and the source electrode may be connected to an anode electrode of the organic light emitting diode OLED.

The storage capacitor C may hold the data voltage applied from the switching TFT ST to the driving TFT DT constant for one frame of the display panel 110.

An organic light emitting diode OLED may be connected to a driving TFT DT and may generate light having a predetermined brightness according to a driving current applied from the driving TFT DT. The anode electrode of the organic light emitting diode OLED may be connected to the driving TFT DT, and a base voltage VSS may be applied to the cathode electrode through a power line.

A plurality of link lines LL may be formed in the link area L/A of the display panel 110. The plurality of link lines LL may be formed between the display area A/A and the bonding area B/A of the display panel 110. The plurality of link lines LL may include a gate link line GLL and a first data link line DLL.

A gate link line GLL may be formed between a plurality of transmission lines of a flexible circuit board 200 and a gate driving circuit 120. The gate link line GLL may transmit a gate control signal provided from the flexible circuit board 200 to the gate driving circuit 120.

A first data link line DLL may be formed between a plurality of transmission lines of a flexible circuit board 200 and a plurality of data lines DL of a display panel 110. The first data link line DLL may transmit a data voltage provided from a data driving circuit 250 of the flexible circuit board 200 to the plurality of data lines DL.

In addition, the plurality of link lines LL may further include a power link line (not shown) configured to transmit various voltages to a gate driving circuit 120 and each pixel P of the display area A/A.

The bonding area B/A of a display panel 110 may be configured with a plurality of pads to which a flexible circuit board 200 is attached. One end of each of a plurality of transmission lines of the flexible circuit board 200 is attached to the plurality of pads in a corresponding manner. The plurality of pads may be connected to each of a plurality of link lines LL formed in a link area L/A.

Meanwhile, the link area L/A of the display panel 110 may be bent toward the back surface of the display panel 110. Accordingly, in order to maintain the radius of curvature during bending, the thickness of the protective layer formed on the plurality of link lines LL in the link area L/A is reduced compared to other areas. As a result, an open or short defect of the plurality of link lines LL may occur due to external impact, etc.

Accordingly, the organic light emitting display device 100 of the present embodiment may additionally have a link line tester 140 configured in the bonding area B/A of the display panel 110. The link line tester 140 may be a link line test circuit that may test whether a plurality of link lines LL of the display panel 110 are defective.

The link line tester 140 may be connected to one or more pads among the plurality of pads of the bonding area B/A through the test lines of the plurality of link lines. The link line tester 140 may be connected to one or more link lines LL of the link area L/A through the one or more connected pads. The link line tester 140 may output a test signal provided from the test device to the plurality of link lines LL through the test lines of the plurality of link lines and the pads connected thereto. The configuration and operation of the link line tester 140 will be described in detail later with reference to the drawings.

The plurality of driving circuits may include a gate driving circuit 120 and a data driving circuit 250.

The gate driving circuit 120 may be configured in the form of a gate in panel (GIP) on at least one side of the display area A/A. The gate driving circuit 120 may generate a gate signal according to a gate control signal provided through a plurality of transmission lines of the flexible circuit board 200 and a plurality of gate link lines GLL of the link area L/A. The gate driving circuit 120 may sequentially output the gate signal to a plurality of gate lines GL of the display area A/A.

The data driving circuit 250 may be configured in the form of a chip on film (COF) on a flexible circuit board 200. The data driving circuit 250 may generate a data voltage according to a data control signal provided through a plurality of transmission lines of the flexible circuit board 200. The data driving circuit 250 may output the data voltage to a plurality of data lines DL of the display area A/A through a plurality of first data link lines DLL.

The flexible circuit board 200 may have one side bonded to the bonding area B/A of the display panel 110 and the other side connected to an external system. A plurality of transmission lines may be formed on the flexible circuit board 200. The flexible circuit board 200 may transmit control signals, such as a gate control signal and a data control signal, provided from an external system through a plurality of transmission lines to the gate driving circuit 120 and the data driving circuit 250, respectively. In addition, the flexible circuit board 200 may transmit a data voltage output from the data driving circuit 250 to the bonding area B/A through a plurality of transmission lines.

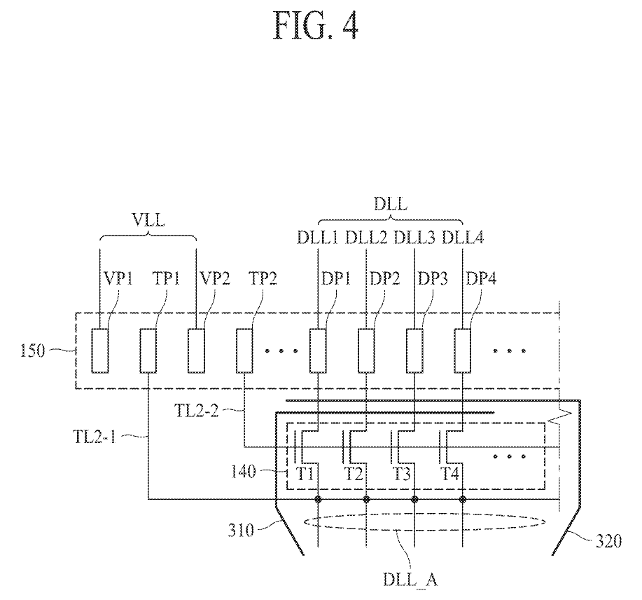

FIG. 4 is a drawing showing a link line tester and a repair line according to one embodiment of the present disclosure.

Referring to FIG. 2 and FIG. 4, a pad portion 150 and a link line tester 140 may be respectively disposed in the bonding area B/A of the display panel 110.

The pad portion 150 may include a number of pads to which one end of each transmission line of the flexible circuit board 200 is attached, such as power pads VP1 and VP2, data pads DP1 to DP4, and test pads TP1 and TP2.

The power pads VP1 and VP2 may be connected to one or more power link lines VLL among a plurality of link lines LL of the link area L/A. The power pads VP1 and VP2 may output power signals, such as a base voltage VSS and a gate low voltage VGL, provided through a power transmission line of a flexible circuit board 200, to the power link lines VLL. The base voltage VSS may be provided to the power line of the display area A/A through the first power pad VP1 and the power link line VLL. The gate low voltage VGL may be provided to the gate driving circuit 120 through the second power pad VP2 and the power link line VLL.

Data pads DP1 to DP4 may be connected to one or more first data link lines DLL among a plurality of link lines LL of a link area L/A. The data pads DP1 to DP4 may output a data voltage provided through a data transmission line of a flexible circuit board 200 to the first data link line DLL. The data voltage is provided to a plurality of data lines DL of a display area A/A through the data pads DP1 to DP4 and the first data link line DLL.

The test pads TP1 and TP2 may be connected to the link line tester 140 through a plurality of second test lines TL2. The test pads TP1 and TP2 may output a test signal applied from a test device to the link line tester 140 through a plurality of second test lines TL2. The test pads TP1 and TP2 may include a first test pad TP1 connected to the link line tester 140 through a 2-1st test line TL2-1 and a second test pad TP2 connected to the link line tester 140 through a 2-2nd test line TL2-2.

The link line tester 140 may include a first TFT T1 to a fourth TFT T4 that are switched by a signal applied from a test device through test pads TP1 and TP2. The present disclosure may illustrate and describe an example of a configuration in which the link line tester 140 includes a first TFT T1 to a fourth TFT T4 that are connected to correspond to the first data pad DP1 to the fourth data pad DP4. The link line tester 140 may include a plurality of switching elements that are connected to correspond to each of a plurality of data pads DP1 to DP4.

The first TFT T1 to the fourth TFT T4 of the link line tester 140 may be respectively connected to the first data pad DP1 to the fourth data pad DP4, and may output a predetermined test signal to a plurality of data pads DP1 to DP4 according to a switching operation.

The first TFT T1 may have a gate electrode connected to the second test pad TP2 through the second-second test line TL2-2, a source electrode connected to the first test pad TP1 through the second-first test line TL2-1, and a drain electrode connected to the first data pad DP1. The first TFT T1 may be turned on by an enable signal provided through the second test pad TP2 and may output a test signal provided through the first test pad TP1 to the first data pad DP1.

The second TFT T2 may have a gate electrode connected to the second test pad TP2 through the second-second test line TL2-2, a source electrode connected to the first test pad TP1 through the second-first test line TL2-1, and a drain electrode connected to the first data pad DP1. The second TFT T2 may be turned on by an enable signal provided through the second test pad TP2 and may output a test signal provided through the first test pad TP1 to the second data pad DP2.

The third TFT T3 may have a gate electrode connected to the second test pad TP2 through the second-second test line TL2-2, a source electrode connected to the first test pad TP1 through the second-first test line TL2-1, and a drain electrode connected to the first data pad DP1. The third TFT T3 may be turned on by an enable signal provided through the second test pad TP2 and may output a test signal provided through the first test pad TP1 to the third data pad DP3.

The fourth TFT T4 may have a gate electrode connected to the second test pad TP2 through the second-second test line TL2-2, a source electrode connected to the first test pad TP1 through the second-first test line TL2-1, and a drain electrode connected to the first data pad DP1. The fourth TFT T4 is turned on by an enable signal provided through the second test pad TP2 and outputs a test signal provided through the first test pad TP1 to the fourth data pad DP4.

In this way, the first TFT T1 to the fourth TFT T4 of the link line tester 140 may have their respective gate electrodes commonly connected to the second test pad TP2 through the second-second test line TL2-2. Accordingly, the first TFT T1 to the fourth TFT T4 may be turned on by an enable signal applied to each gate electrode and may simultaneously output a test signal provided from the first test pad TP1 to the first data pad DP1 to the fourth data pad DP4.

A test signal output from a link line tester 140 may be simultaneously applied to a plurality of link lines, for example, a first sub-data link line DLL1 to a fourth sub-data link line DLL4, connected thereto via a first data pad DP1 to a fourth data pad DP4. At this time, the link line tester 140 may output a test signal to the first data pad DP1 to the fourth data pad DP4 for at least one frame of the display panel 110.

In this way, by the operation of the link line tester 140, a plurality of pixels P of the display area A/A of the display panel 110 emit light. At this time, if an open failure occurs in at least one link line among the first sub-data link line DLL1 to the fourth sub-data link line DLL4, the pixel P connected to the corresponding link line and data line does not emit light. Therefore, the link line tester 140 may detect at least one link line in which an open failure occurs among the first sub-data link line DLL1 to the fourth sub-data link line DLL4.

Meanwhile, the link line tester 140 may operate only while testing open defects of a plurality of link lines LL. Accordingly, the link line tester 140 of the present embodiment may stop test operation by the flexible circuit board 200 attached to the pad portion 150 after the defect test of the link line is completed.

To explain more specifically, when the link line test by the link line tester 140 is completed, one end of one of one of one of one of the transmission lines of the flexible circuit board 200 may be attached to one end of one of the pads of the pad portion 150. At this time, the first test pad TP1 of the pad portion 150 may be attached to one end of the first power transmission line of the flexible circuit board 200 together with the adjacent first power pad VP1. In addition, the second test pad TP2 may be attached to one end of the second power transmission line of the flexible circuit board 200 together with the adjacent second power pad VP2. Accordingly, the base voltage VSS may be applied to the first test pad TP1 through the first power transmission line, and the gate low voltage VGL may be applied to the second test pad TP2 through the second power transmission line. Accordingly, the first TFT T1 to the fourth TFT T4 of the link line tester 140 may be turned off by the gate low voltage VGL applied to each gate electrode, so the link line tester 140 does not operate.

In this way, the link line tester 140 of the present embodiment may stop the test operation by attaching the flexible circuit board 200 to the pad portion 150 after the open defect test of the link line is completed. Therefore, in the organic light emitting display device 100 of the present disclosure, an additional process such as laser trimming for cutting the connection of the link line tester 140 after the defect test of the link line may be omitted.

Referring to FIG. 4, the first repair line 310 may be connected to the data driving circuit 250 and may be positioned on the leftmost outer line among the second data link lines DLL_A connecting the data driving circuit 250 and the link line tester 140 and may surround the left side of the link line tester 140 and may be disposed in the link area LA between the link line tester 140 and the display area AA.

The second repair line 320 may be connected to the data driving circuit 250 and may be disposed on the rightmost outer line among the second data link lines DLL_A connecting the data driving circuit 250 and the link line tester 140 and may surround the right side of the link line tester 140 and may be disposed in the link area LA between the link line tester 140 and the display area AA.

When one of the second data link lines DLL_A connecting the data drive circuit 250 and the link line tester 140 is disconnected, the first and second repair lines 310 and 320 may be fused to the corresponding first data link line in the link area LA using a predetermined welding method. As a result, the signal voltage applied to the disconnected second data link line may be applied to the corresponding first data link line of the link area LA through the repair line.

In this way, when one of the second data link lines DLL_A connecting the data drive circuit 250 and the link line tester 140 is disconnected, the first and second repair lines 310 and 320 may be easily repaired since a signal voltage may be applied through the repair line that replaces the disconnected data link line.

As described above, the organic light emitting display device 100 of the present embodiment may be configured to additionally include a link line tester 140 connected to a plurality of pads in the bonding area B/A of the display panel 110, thereby enabling easy detection of open-circuit defects in a plurality of link lines LL of the display panel 110 in a chip-on-film structure. Furthermore, a disconnection in any of the second data link lines DLL_A, which connect the link line tester 140 and the data driving circuit 250 of the flexible circuit board 200 through a repair line, may be easily repaired.

In addition, the organic light emitting display device 100 may stop the operation of the link line tester 140 after completion of the link line open defect inspection using the link line tester 140, by attaching the flexible circuit board 200 to the plurality of pads. As a result, an additional cutting process may be omitted, thereby reducing manufacturing costs and simplifying the manufacturing process.

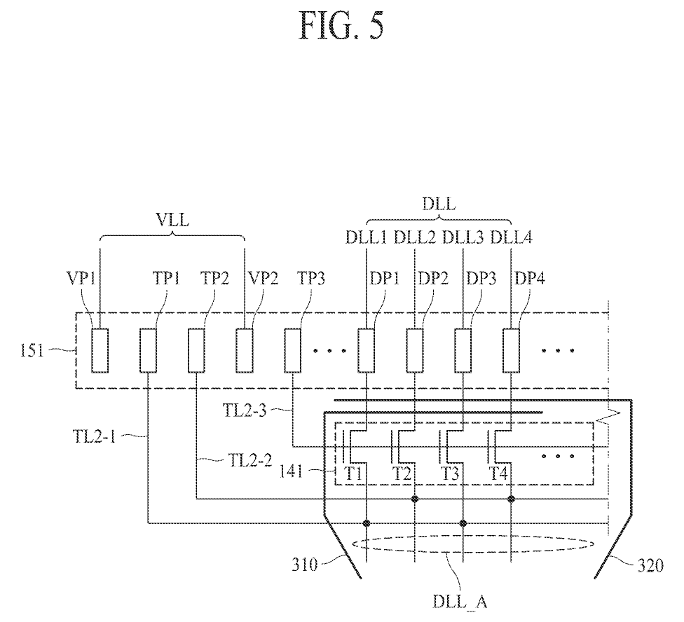

FIG. 5 is a drawing showing a link line tester according to another embodiment of the present invention.

Hereinafter, the link line tester 141 capable of detecting both open defects and short defects of a plurality of link lines LL of a display panel 110 will be described in detail. The link line tester 141 illustrated in FIG. 5 may have a substantially similar configuration to the link line tester 140 described above in FIG. 4, except that a test signal is provided through three test pads TP1 to TP3 configured in a pad portion 151. Accordingly, a detailed description of the same components will be omitted.

Referring to FIG. 2 and FIG. 5, a pad portion 151 and a link line test portion 141 may be disposed in the bonding area B/A of the display panel 110.

The pad portion 151 may include a plurality of power pads VP1 and VP2, a plurality of data pads DP1 to DP4, and a plurality of test pads (TP1, TP2, TP3) to which a flexible circuit board 200 is attached.

The plurality of power pads VP1 and VP2 may be connected to a plurality of power link lines VLL. The plurality of power pads VP1 and VP2 may output a base voltage VSS and a gate low voltage VGL provided through a power transmission line of the flexible circuit board 200 to the power link lines VLL.

A plurality of data pads DP1 to DP4 may be connected to a plurality of data link lines DLL. A plurality of data pads DP1 to DP4 may output a data voltage provided through a data transmission line of a flexible circuit board 200 to a first data link line DLL.

The plurality of test pads TP1 to TP3 may be connected to a link line tester 141 through a plurality of second test lines TL2. The plurality of test pads TP1 to TP3 may output test signals applied from a test device to the link line tester 141 through a plurality of second test lines TL2. The plurality of test pads TP1 to TP3 may include a first test pad TP1 connected to the link line tester 141 through a 2-1st test line TL2-1, a second test pad TP2 connected to the link line tester 141 through a 2-2nd test line TL2-2, and a third test pad TP3 connected to the link line tester 141 through a 2-3rd test line TL2-3.

The link line tester 141 may include a plurality of switching elements, for example, the first TFT T1 to the fourth TFT T4, which are switched by an enable signal applied from the test device through a plurality of test pads TP1 to TP3. The first TFT T1 to the fourth TFT T4 may have one electrode connected to correspond to a plurality of data pads DP1 to DP4, respectively, and may output a predetermined test signal to the plurality of data pads DP1 to DP4 according to the switching operation.

The gate electrodes of each of the first TFT T1 to the fourth TFT T4 may be commonly connected to the third test pad TP3 through the second-third test line TL2-3. The drain electrodes of each of the first TFT T1 to the fourth TFT T4 may be connected to corresponding data pads, i.e., the first data pad DP1 to the fourth data pad DP4, respectively.

In this case, the source electrodes of the odd-numbered TFTs, i.e., the first TFT T1 and the third TFT T3, among the first TFT T1 to the fourth TFT T4, may be connected to the first test pad TP1 through the second-first test line TL2-1. In addition, the source electrodes of the even-numbered TFTs, i.e., the second TFT T2 and the fourth TFT T4, among the first TFT T1 to the fourth TFT T4, may be connected to the second test pad TP2 through the second-second test line TL2-2.

The first TFT T1 to the fourth TFT T4 may be simultaneously turned on by an enable signal provided from the third test pad TP3 through the second-third test line TL2-3.

The first TFT T1 and the third TFT T3 may output a first test signal provided from the first test pad TP1 through the second-first test line TL2-1 to the first data pad DP1 and the third data pad DP3, respectively. In addition, the second TFT T2 and the fourth TFT T4 may output a second test signal provided from the second test pad TP2 through the second-second test line TL2-2 to the second data pad DP2 and the fourth data pad DP4, respectively. In this case, the test device may apply an enable signal to the third test pad TP3 during one frame of the display panel 110.

In this way, by the operation of the link line tester 141, a plurality of pixels P of the display area A/A of the display panel 110 may emit light. At this time, if an open failure occurs in at least one link line among the first sub-data link line DLL1 to the fourth sub-data link line DLL4, the pixel P connected to the corresponding link line and data line may not emit light. Therefore, the link line tester 141 may detect at least one link line in which an open failure occurs among the first sub-data link line DLL1 to the fourth sub-data link line DLL4.

Accordingly, the link line tester 141 may detect that a short circuit defect has occurred in at least one of the first sub data link line DLL1 to the fourth data link line DLL4.

More specifically, if a short circuit defect occurs between the first sub-data link line DLL1 and the second sub-data link line DLL2 adjacent thereto, the first test signal of high level applied from the link line tester 141 to the first sub-data link line DLL1 may be also applied to the second sub-data link line DLL2. Accordingly, during one 1/2 frame of the display panel 110, the pixel P connected to the first sub-data line (DL1) and the pixel P connected to the second data line DL2 may emit light simultaneously. In addition, if a short circuit defect occurs between the second sub-data link line DLL2 and the third sub-data link line DLL3 adjacent thereto, the second test signal of high level applied from the link line tester 141 to the second sub-data link line DLL2 may be also applied to the third sub-data link line DLL3. Due to this, during another half frame of the display panel 110, the pixel P connected to the second data line DL2 and the pixel P connected to the third data line DL3 may emit light simultaneously. Accordingly, the link line tester 141 may detect at least one pair of link lines in which a short circuit defect has occurred among the first sub-data link line DLL1 to the fourth sub-data link line DLL4 by the above-described operation.

As described above, the link line tester 141 may be stopped from operating by the flexible circuit board 200 after the defect test of a plurality of link lines is completed. That is, the first test pad TP1 and the second test pad TP2 of the pad portion 150 may be attached to one end of the first power transmission line of the flexible circuit board 200 together with the adjacent first power pad VP1. Therefore, the base voltage VSS may be applied to the first test pad TP1 and the second test pad TP2 through the first power transmission line. In addition, the third test pad TP3 of the pad portion 150 may be attached to one end of the second power transmission line of the flexible circuit board 200 together with the adjacent second power pad VP2. Therefore, the gate low voltage VGL may be applied to the third test pad TP3 through the second power transmission line.

In this way, since the base voltage VSS and the gate low voltage VGL are applied to the first test pad TP1 to the third test pad TP3 by the flexible circuit board 200, the link line tester 141 connected to the first test pad TP1 to the third test pad TP3 may stop operating. Therefore, the organic light emitting display device 100 of the present disclosure may omit an additional process of cutting between the link line tester 141 and a plurality of data pads DP1 to DP4 connected thereto after the open and short defect test of the link line is performed.

Referring to FIG. 5, the first repair line 310 may surround the leftmost outer line among the second data link lines DLL_A, which connects the data driving circuit and the link line tester 140, as well as a left side of the link line tester 140. The first repair line 310 may be disposed in a link area LA between the link line tester 140 and the display area AA.

The second repair line 320 may surround the rightmost outer line among the second data link lines DLL_A, which connects the data driving circuit and the link line tester 140, as well as a right side of the link line tester 140. The first repair line 310 may be disposed in a link area LA between the link line tester 140 and the display area AA.

When one of the second data link lines DLL_A connecting the data drive circuit and the link line tester 140 is disconnected, the first and second repair lines 310 and 320 may weld the first data link line of the link area LA corresponding to the disconnected second data link line to the repair line using a predetermined welding method, thereby allowing a signal voltage applied to the disconnected second data link line to be applied to the corresponding first data link line of the link area LA through the repair line.

In this way, when one of the second data link lines DLL_A connecting the data drive circuit and the link line tester 140 is disconnected, the first and second repair lines 310 and 320 may be easily repaired since a signal voltage may be applied through the repair line that replaces the disconnected data link line.

As described above, the organic light emitting display device 100 of the present embodiment additionally may configure a link line tester 141 connected to a plurality of pads in the bonding area B/A of the display panel 110, thereby making it possible to easily detect open and short defects of a plurality of link lines LL of the display panel 110 in the organic light emitting display device 100 of the chip-on-film structure, and easily may repair an disconnection of a second data link line DLL_A connecting the link line tester 140 and the data driving circuit 250 of the flexible circuit board 200 through the repair line.

In addition, after the test for open and short defects of the link lines using the link line tester 141 is completed, the organic light emitting display device 100 may stop the operation of the link line tester 141 by attaching the flexible circuit board 200 to a plurality of pads. As a result, an additional cutting process can be omitted, thereby reducing manufacturing costs and simplifying the manufacturing process.

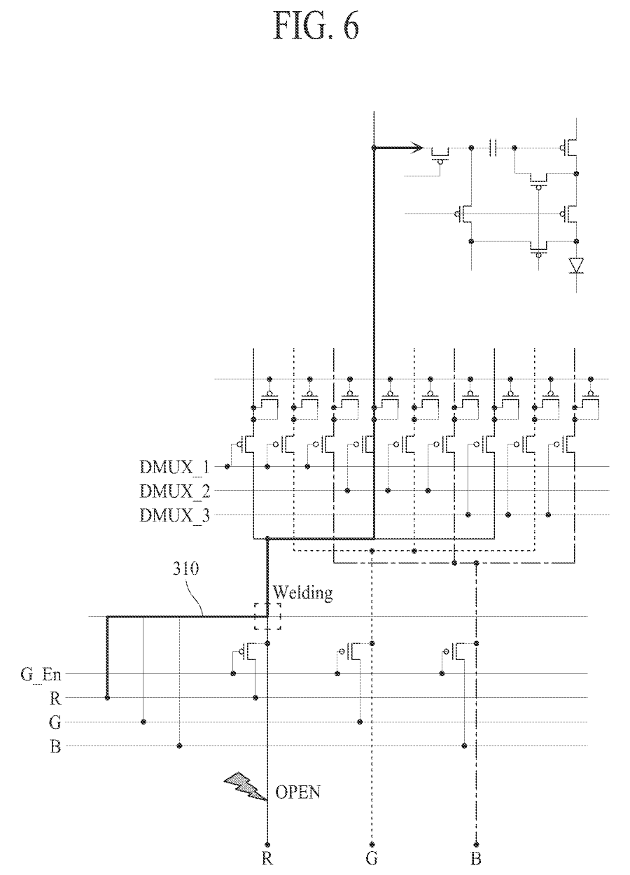

FIG. 6 is a drawing showing an example to which the repair line of embodiments of the present disclosure is applied.

FIG. 6, referring together to FIG. 2 and FIGS. 4 to 5, is intended to explain an example in which a signal voltage is applied by applying a repair line that replaces a disconnected second sub-data link line when one of the second data link lines DLL_A connecting the data drive circuit 250 and the link line tester 140 is disconnected.

In the lower portion of FIG. 6, second sub data link lines of R, G, and B may be disposed from left to right, but may be disposed repetitively in the order of R, G, and B. When the R second sub data line link among the R, G, and B second sub data link lines is disconnected, a signal voltage may be applied through the repair line that replaces the disconnected R second sub-data link line by welding the intersection between the R first sub-data link line in the corresponding link area and the repair line 310

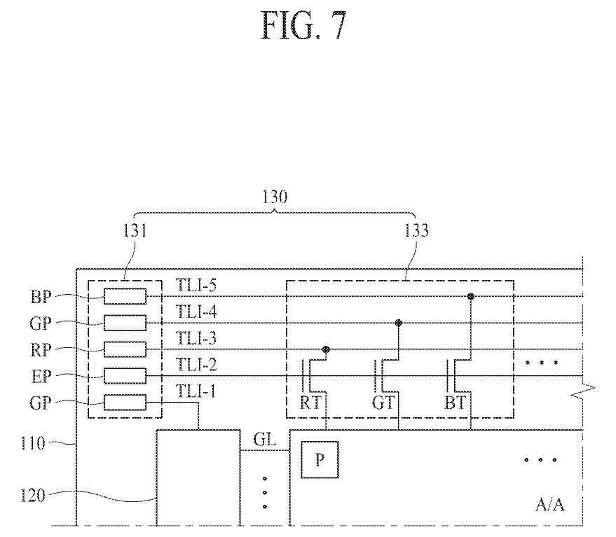

FIG. 7 is a drawing showing a pixel tester according to one embodiment of the present invention.

Referring to FIG. 2 and FIG. 7, a pixel tester 130 may be arranged in a test area T/A of a display panel 110. The pixel tester 130 may include a plurality of pads 131 to which various signals are applied from a test device, and a plurality of switching elements 133 respectively connected to the plurality of pads 131 through a plurality of first test lines TL1. The plurality of pads 131 may include a first pad GP to a fifth pad BP. The plurality of switching elements 133 may include a plurality of R TFTs RT, a plurality of G TFTs GT, and a plurality of B TFTs BT.

The first pad GP may be connected to the gate driving circuit 120 through the 1-1 test line TL1-1. The first pad GP may output a gate control signal applied from the test device to the gate driving circuit 120 through the 1-1 test line TL1-1. The gate driving circuit 120 may generate a gate signal according to the gate control signal and may sequentially output the same to a plurality of gate lines GL of the display area A/A.

The second pad EP may be connected to the gate electrodes of each of the plurality of switching elements 133 through the first-second test line TL1-2. The second pad EP may output an enable signal applied from the test device to the gate electrodes of each of the plurality of switching elements 133 through the first-second test line TL1-2. The plurality of switching elements 133 may perform a switching operation according to the enable signal.

The third pad RP may be connected to the drain electrodes of a plurality of R TFTs RTs through the first-third test line TL1-3. The third pad RP may output a first test signal, for example, an R data signal, applied from a test device to the drain electrodes of the plurality of R TFTs RTs through the first-third test line TL1-3. The plurality of R TFTs RTs may output the R data signal to a corresponding data line among a plurality of data lines DL of a display area A/A during a period in which they are turned on by an enable signal.

The fourth pad GP may be connected to the drain electrodes of a plurality of G TFTs GTs through the first-fourth test lines TL1-4. The fourth pad GP may output a second test signal, e.g., a G data signal, applied from a test device to the drain electrodes of the plurality of G TFTs GTs through the first-fourth test lines TL1-4. The plurality of G TFTs GTs may output the G data signal to a corresponding data line among a plurality of data lines DL of a display area A/A during a period in which they are turned on by an enable signal.

The fifth pad BP may be connected to the drain electrodes of a plurality of B TFTs BT through the 1-5th test line TL1-5. The fifth pad BP may output a third test signal, e.g., a B data signal, applied from a test device to the drain electrodes of the plurality of B TFTs BT through the 1-5th test line TL1-5. The plurality of B TFTs BT may output the B data signal to a corresponding data line among a plurality of data lines DL of a display area A/A during a period in which they are turned on by an enable signal.

The organic light emitting display device 100 of the present embodiment may perform pixel performance testing using the pixel testing unit 130 and link line defect testing using the link line testing unit 140 for one frame each. However, the present invention is not limited thereto, and the organic light emitting display device 100 may perform both pixel performance testing and link line defect testing for one frame.

First, during the first frame of the organic light emitting display device 100, a gate control signal may be applied from the test device to the first pad GP of the pixel tester 130. The gate driving circuit 120 may generate a gate signal (GS) according to the gate control signal provided through the first pad GP and the first-first test line TL1-1, and sequentially output the same to a plurality of gate lines GL of the display area A/A.

At the same time, a high-level first enable signal may be applied to a first test pad TP1 among a plurality of pads in the bonding area B/A from the test device, and a high-level test signal may be applied to a second test pad TP2. The high-level first enable signal and the test signal may be applied for one frame of the display panel 110.

The first TFT T1 to the fourth TFT T4 of the link line tester 140 may be simultaneously turned on by a first enable signal of a high level. Then, the turned-on first TFT T1 to fourth TFT T4 may output a high level test signal to the first sub data link line DLL1 to the fourth sub data link line DLL4 through the first data pad DP1 to the fourth data pad DP4. At this time, signals may not be applied from the test device to the second pad EP to the fifth pad BP of the pixel tester 130.

Accordingly, the organic light emitting display device 100 may perform an open defect test on a plurality of link lines LL of the display panel 110 using the link line tester 140. That is, the organic light emitting display device 100 of the present embodiment may operate the gate driving circuit 120 using the pixel tester 130 during one frame operation to output a gate signal to a plurality of gate lines GL of the display area A/A. At the same time, a test signal may be simultaneously output from the link line tester 140 to the first data link line DLL to detect an open defect occurring in at least one link line among the plurality of data link lines DLL.

Next, during the second frame of the organic light emitting display device 100, a gate control signal may be applied from the test device to the first pad GP of the pixel tester 130. The gate driving circuit 120 may generate a gate signal GS according to the gate control signal provided through the first pad GP and the first-first test line TL1-1, and may sequentially output the same to a plurality of gate lines GL of the display area A/A.

At the same time, the test device may apply a second enable signal having a high level to the second pad EP of the pixel tester 130 and may sequentially apply a data signal having a high level for 1/3 of a frame to each of the third pad RP to the fifth pad BP.

For example, the test device may apply a high-level R data signal to the third pad RP during the first 1/3 frame, a high-level G data signal to the fourth pad GP during the second 1/3 frame, and a high-level B data signal to the fifth pad BP during the third 1/3 frame. In this case, the second enable signal at the high level may be applied to the second pad EP for one frame. Meanwhile, while signals are applied to all pads of the pixel tester 130 from the test device, the link line tester 140 may not operate.

The R TFT RT, G TFT GT and B TFT BT of the pixel tester 130 may be simultaneously turned on by a high-level second enable signal. The turned-on R TFT RT may output an R data signal to the data line DL of the display area A/A during the first 1/3 frame. Then, the turned-on G TFT GT may output a G data signal to the data line DL of the display area A/A during the second 1/3 frame. Finally, the turned-on B TFT BT may output a B data signal DATA_B to the data line DL of the display area A/A during the third 1/3 frame.

In this case, the R data signal, the G data signal, and the B data signal may be data having a predetermined grayscale level. Accordingly, each pixel P of the display area A/A may be emitted with a predetermined luminance by the R data signal, the G data signal, and the B data signal applied through the data line DL. Accordingly, the pixel tester 130 may test the operating performance of each pixel P of the display panel 110.

Although many things have been specifically described in the foregoing description, they should be construed as examples of embodiments rather than limiting the scope of the invention. Accordingly, the invention should not be defined by the described embodiments, but by the claims and their equivalents.

The display device of the present disclosure may easily detect link line defects by configuring a link line tester in a bonding area of a display panel to test open and short defects in link lines of a link area of a display panel, and may easily repair a disconnection of a data link line connecting the link line tester and a data drive circuit through a repair line.

In addition, after the display device has finished testing for open and short defects in the link line using the link line tester, the operation of the link line tester is stopped using a flexible circuit board attached to the bonding area, thereby omitting the cutting process of the link line tester in the manufacturing process of the display device. Accordingly, the manufacturing cost of the display device may be reduced and the manufacturing process may be simplified.

What is claimed is:

1. A display device comprising:
a display panel including a display area, a bonding area, and a link area;
a link line tester in the bonding area of the display panel, the link line tester configured to detect link line defects in the link area;
a flexible circuit board having one side connected to the bonding area of the display panel, the flexible circuit board including a data driving circuit connected to the link line tester through data link lines; and
a repair line surrounding an outermost link line among the data link lines and a side of the link line tester, the repair line between the link line tester and the display area.

2. The display device of claim 1, wherein:
the bonding area includes a first test pad, a second test pad, and a plurality of data pads,
the link line tester includes a plurality of thin film transistors (TFTs), and
each of the plurality of TFTs includes a gate electrode commonly connected to the second test pad, a source electrode commonly connected to the first test pad, and a drain electrode connected to a corresponding one of the plurality of data pads.

3. The display device of claim 2, wherein the plurality of TFTs are turned on according to an enable signal provided through the second test pad, and simultaneously output a test signal to the plurality of data pads.

4. The display device of claim 1, wherein:
the bonding area includes a first test pad, a second test pad, a third test pad, and a plurality of data pads,
the link line tester includes a plurality of thin film transistors (TFTs),
each of the plurality of TFTs includes a gate electrode commonly connected to the third test pad and a drain electrode connected to a corresponding one of the plurality of data pads, and
the plurality of TFTs includes an odd-numbered TFT having a source electrode connected to the first test pad and an even-numbered TFT having a source electrode connected to the second test pad.

5. The display device of claim 4, wherein the odd-numbered TFT and the even-numbered TFT are turned on according to an enable signal provided through the third test pad, and alternately output a test signal to a plurality of link lines.

6. The display device of claim 5, wherein each of the odd-numbered TFT and the even-numbered TFT alternately outputs the test signal for every half-frame.

7. The display device of claim 1, wherein an operation of the link line tester is interrupted by the flexible circuit board.

8. The display device of claim 1 further comprising:
a gate driving circuit on at least one side of the display area; and
a pixel tester in a test area on an upper portion of the display area, the pixel tester configured to test operation performance of each of a plurality of pixels,
wherein the pixel tester is further configured to operate the gate driving circuit during a defect detection operation of the link line tester.

9. The display device of claim 8, wherein the pixel tester includes a plurality of switching elements that alternately output a red data signal, a green data signal, and a blue data signal to each of the plurality of pixels.

10. The display device of claim 9, wherein the plurality of switching elements alternately output the red data signal, the green data signal, and the blue data signal for every one-third frame.
